(19) United States
(12) Patent Application Publication
(10) Pub. No.: US 2012/0219087 A1
(43) Pub. Date: Aug. 30, 2012

(54) APPARATUS AND METHOD FOR IMPROVING HIGH-POWER SIGNAL RECEIVING PERFORMANCE USING LOW-POWER SIGNALS

(75) Inventors: Hyoungsoo Lim, Daejeon (KR); Heung Mook Kim, Daejeon (KR)

(73) Assignee: Electronics and Telecommunications Research Institute, Daejeon (KR)

(21) Appl. No.: 13/504,777

(22) PCT Filed: Oct. 4, 2010
(86) PCT No.: PCT/KR2010/006743

§ 371 Date: Apr. 27, 2012

(30) Foreign Application Priority Data
Oct. 29, 2009 (KR) 10-2009-0103479
Aug. 26, 2010 (KR) 10-2010-0082856

(51) Int. Cl. H04L 27/00; H03K 9/00

(52) U.S. Cl. 375/295; 375/316

(57) ABSTRACT

Provided are an apparatus and a method for enhancing a reception performance of a high power signal using a low power signal. Main service data and supplementary information data that may supplement the main service data may be hierarchically modulated and be transmitted. The main service data may be modulated as a high power signal to be transmitted, and the supplementary information data may be modulated as a low power signal to be transmitted.

### TECHNICAL FIELD

The present invention relates to a transmission system configured with a hierarchical modulation technology, and a low power signal and a high power signal.

### BACKGROUND ART

Similar to a hierarchical modulation, it is described that all transmission standards that adopt a signal transmission scheme configured with a low power signal and a high power signal, transmit different information to each of the low power signal and the high power signal.

The high power signal is used in the case of relatively high importance, relatively high data transmission speed, or needing a higher reception electric power to guarantee a reception performance, and the low power signal may be used in an opposite case. In most cases, a main service is provided using the high power signal, and additional service data is provided using the low power signal.

However, when the low power signal to be transmitted to provide the additional service data is transmitted simultaneously with the high power signal, the low power signal may act as an interference signal against the high power signal, and may degrade a reception performance of the high power signal providing the main service.

### DISCLOSURE OF INVENTION

### Technical Goals

An aspect of the present invention provides an apparatus and a method that may enhance a reception performance with respect to a main service signal by transmitting supplementary information with respect to the main service signal using a low power signal.

### Technical solutions

According to an aspect of the present invention, there is provided a hierarchical transmission apparatus that may include a main service modulator to modulate main service data, a supplementary information generator to generate supplementary information data associated with the main service data based on the main service data, a supplementary information modulator to modulate the supplementary information data, a signal combiner to combine an output of the main service modulator and an output of the supplementary information modulator, and a signal transmitter to transmit a signal generated by combining the output of the main service modulator and the output of the supplementary information modulator.

The supplementary information generator may generate the supplementary information data associated with the main service data based on a predetermined standard to enhance a reception performance of the main service data.

The main service modulator may modulate the main service data using a modulation scheme having a same bitrate as a bitrate of a modulation scheme of the supplementary information modulator, or having a higher bitrate than the bitrate of the modulation scheme of the supplementary information modulator.

Each of the main service modulator and the supplementary information modulator may respectively modulate each of the main service data and the supplementary information data, each using a different modulation scheme.

The main service modulator may include a channel encoder to perform a channel coding with respect to the main service data.

The supplementary information modulator may include a channel encoder to perform a channel coding with respect to the supplementary information data.

The signal combiner may combine an output of the main service modulator and an output of the supplementary information modulator using a superposition coding scheme or using a superposition modulating scheme.

According to an aspect of the present invention, there is also provided a hierarchical transmission method that may include modulating main service data, generating supplementary information data associated with the main service data based on the main service data, modulating the supplementary information data, combining the modulated main service data and the modulated supplementary information data, and transmitting the combined data.

The generating of the supplementary information data may include generating the supplementary information data associated with the main service data based on a predetermined standard to enhance a reception performance of the main service data.

The modulating of the main service data may include modulating the main service data using a modulation scheme having a same bitrate as a bitrate of a modulation scheme of the modulating of the supplementary information data, or having a higher bitrate than the bitrate of the modulation scheme of the modulating of the supplementary information data.

Each of the modulating of the main service data and the modulating of the supplementary information data may respectively include modulating each of the main service data and the supplementary information data, each using a different modulation scheme.

The modulating of the main service data may include performing a channel coding with respect to the main service data.

The modulating of the supplementary information data may include performing a channel coding with respect to the supplementary information data.

The combining of the modulated main service data and the modulated supplementary information data may include combining the modulated main service data and the modulated supplementary information data using a superposition coding scheme or using a superposition modulating scheme.

According to an aspect of the present invention, there is also provided a reception apparatus of a hierarchical transmission signal that may include an antenna to receive a signal from a transmission apparatus, and a demodulator to demodulate the received signal, wherein the signal is generated by combining modulated main service data and modulated supplementary information data.

The supplementary information data may be associated with the main service data, and may be generated based on a predetermined standard to enhance a reception performance of the main service data.

A bitrate of the main service data may be same as a bitrate of the supplementary information data, or higher than the bitrate of the supplementary information data.

### Effect of the Invention

According to embodiments of the present invention, it is possible to enhance a reception performance of main service data by hierarchically modulating the main service data and supplementary information data that may supplement the main service data, and by transmitting the hierarchically modulated main service data and the hierarchically modulated supplementary information data.

Also, according to embodiments of the present invention, it is possible to transmit supplementary information with respect to a high power signal using a low power signal. Thus, the low power signal may not act as interference against the high power signal. Consequently, it is possible to enhance a reception performance with respect to the high power signal by transmitting the supplementary information with respect to the power signal along with the high power signal.

Also, according to embodiments of the present invention, it is possible to modulate each of main service data and supplementary information data, each using a different modulation scheme. Accordingly, a reception performance with respect to a main service signal may consequently be enhanced by determining an adaptive modulation scheme based on a status of a channel.

### BRIEF DESCRIPTION OF DRAWINGS

FIG. 1 is a block diagram illustrating an example of a hierarchical transmission apparatus that may transmit additional service data using a low power signal;

FIG. 2 is a diagram illustrating a main service signal that may be degraded due to the main service signal being combined with additional service data in comparison with a main service signal that is not combined with additional service data;

FIG. 3 is a diagram illustrating a hierarchical transmission apparatus that may enhance a reception performance of a high power signal using a low power signal according to embodiments of the present invention; and

FIG. 4 is a flowchart illustrating an operation with respect to a hierarchical transmission method that may enhance a reception performance of a high power signal using a low power signal according to embodiments of the present invention.

### BEST MODE FOR CARRYING OUT THE INVENTION

Reference will now be made in detail to embodiments of the present invention, examples of which are illustrated in the accompanying drawings, wherein like reference numerals refer to the like elements throughout. The embodiments are described below in order to explain the present invention by referring to the figures.

When it is determined detailed description related to a related known function or configuration they may make the purpose of the present invention unnecessarily ambiguous in describing the present invention, the detailed description will be omitted here. Also, terminologies used herein are defined to appropriately describe the exemplary embodiments of the present invention and thus may be changed depending on a user, the intent of an operator, or a custom. Accordingly, the terminologies must be defined based on the following overall description of this specification.

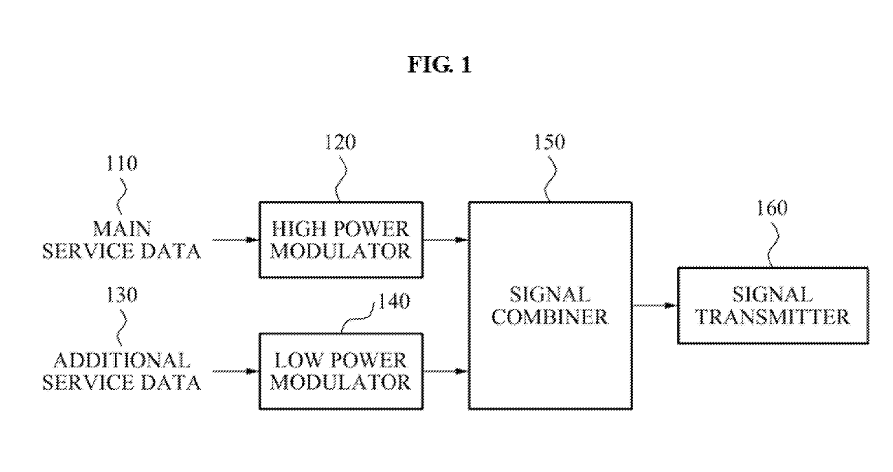

FIG. 1 is a block diagram illustrating an example of a hierarchical transmission apparatus that may transmit additional service data using a low power signal.

Referring to FIG. 1, the hierarchical transmission apparatus may include a high power modulator 120, a low power modulator 140, a signal combiner 150, and a signal transmitter 160.

The high power modulator 120 may modulate main service data 110 as a high power signal.

The low power modulator 140 may modulate additional service data 120 as a low power signal.

The signal combiner 150 may combine signals modulated by the high power modulator 120 and the low power modulator 140.

The signal transmitter 160 may transmit an output of the signal combiner 150.

According to the hierarchical transmission apparatus as described above, a maximum data transmission speed may increase, however, a low power additional service signal may act as an interference signal against a high power main service signal, and may degrade a reception performance of the main service signal in a reception apparatus.

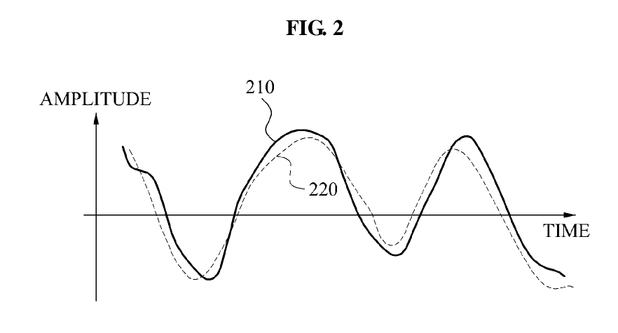

FIG. 2 is a diagram illustrating a main service signal that may be degraded due to the main service signal being combined with additional service data in comparison with a main service signal that is not combined with additional service data.

Referring to FIG. 2, a line corresponds to the main service signal 210 that may be degraded due to the main service signal being combined with the additional service. A dotted line corresponds to the main service signal 220 that is not combined with the additional service data.

When an additional service signal generated by modulating additional service data as a low power signal is added to a main service signal generated by modulating main service data as a high power signal, a final signal to be transmitted may become different from the main service signal by a magnitude of the low power signal, that is, the additional service signal that may be added to the main service signal. The additional service signal may be noise in transmitting the main service signal, and accordingly a reception performance with respect to the main service signal in the reception apparatus may decline.

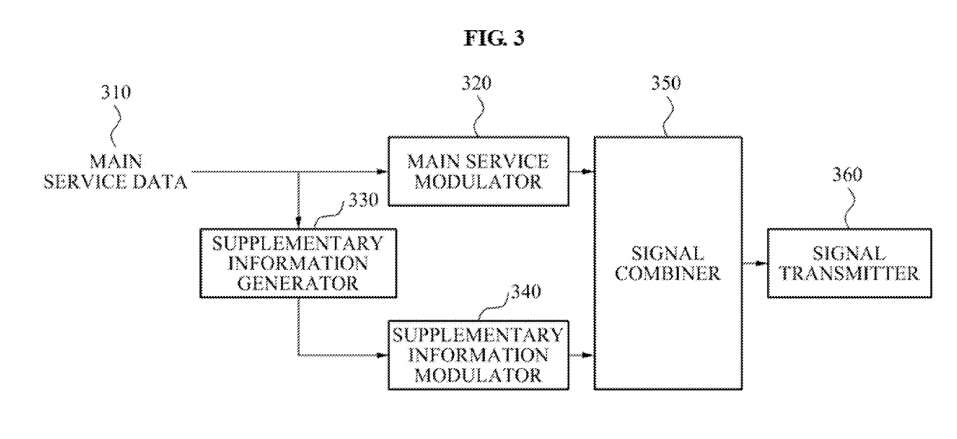

FIG. 3 is a diagram illustrating a hierarchical transmission apparatus that may enhance a reception performance of a high power signal using a low power signal according to embodiments of the present invention.

Referring to FIG. 3, the hierarchical transmission apparatus may include a main service modulator 320, a supplementary information generator 330, a supplementary information modulator 340, a signal combiner 350, and a signal transmitter 360.

The main service modulator 320 may modulate main service data 310. The main service modulator 320 may generate a main service modulation signal by modulating the main service data 310. Here, the main service modulator 320 may include a main service channel encoder. The main service channel encoder may perform a channel coding with respect to the main service data 310.

The supplementary information generator 330 may generate supplementary information data associated with the main service data based on the main service data 310. Here, the supplementary information data may refer to data that may be associated with the main service data 310 based on a predetermined standard to enhance a reception performance of the main service data 310.

The supplementary information modulator 340 may modulate the supplementary information data generated by the supplementary information generator 330. The supplementary information modulator 340 may generate a supplementary information modulation signal by modulating the supplementary information data. The supplementary information modulator 340 may include a supplementary information channel encoder. The supplementary information channel encoder may perform a channel coding with respect to the supplementary information data.

The signal combiner 350 may combine an output of the main service modulator 320 and an output of the supplementary information modulator 340. The signal combiner 350 may combine the main service modulation signal and the supplementary information modulation signal. The signal combiner 350 may combine the output of the main service modulator and the output of the supplementary information modulator using a superposition coding scheme or a superposition modulating scheme.

The signal transmitter 360 may transmit a signal generated by combining the output of the main service modulator and the output of the supplementary information modulator. The signal transmitter 360 may transmit, to a reception apparatus, a signal where the main service modulation signal and the supplementary information modulation signal are combined.

Here, each of the main service modulator 320 and the supplementary information modulator 340 may respectively modulate each of the main service data 310 and the supplementary information data, each using a different modulation scheme.

Particularly, the main service modulator 320 may modulate the main service data 310 using a modulation scheme that has a higher bitrate than a bitrate of a modulation scheme that the supplementary information modulator 340 uses. For example, when the supplementary information modulator 340 modulates supplementary information using a BPSK modulation scheme or using a QPSK modulation scheme, the main service modulator 320 may modulate the main service data 310 using a modulation scheme such as a 16-QAM modulation scheme that has a higher bitrate than the BPSK modulation scheme or the QPSK modulation scheme.

The main service modulation signal corresponding to an output of the main service modulator 320 may have a higher transmission electric power than the supplementary information modulation signal corresponding to an output of the supplementary information modulator 340.

As described above, the hierarchical transmission may transmit supplementary information data associated with the main service data, as opposed to transmitting additional service data using a low power signal. Thus, the hierarchical transmission apparatus may enhance a reception performance of a main service signal more than when a hierarchical transmission is not used, or in the case of a conventional hierarchical transmission scheme that may transmit additional service data using a low power signal. The hierarchical transmission apparatus may transmit, using a low power signal, supplementary information data with respect to main service data corresponding to a high power signal, thereby enhancing a reception performance of the high power signal using the low power signal.

According to embodiments of the present invention, a reception apparatus corresponding to a hierarchical transmission apparatus to enhance a reception performance of a high power signal using a low power signal, may include an antenna to receive a signal from a transmission apparatus, and a demodulator to demodulate the signal received via the antenna. The signal received by the reception apparatus may correspond to a signal generated by combining modulated main service data and modulated supplementary information data. The supplementary information data may be associated with the main service data, and may be generated based on a predetermined standard to enhance a reception performance of the main service data has been described above. Also, a bitrate of the modulated main service data may be higher than a bitrate of the modulated supplementary information data.

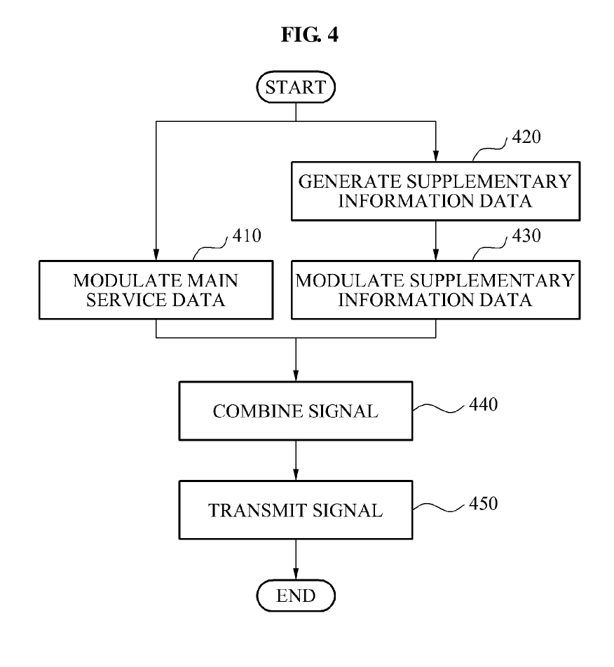

FIG. 4 is a flowchart illustrating an operation with respect to a hierarchical transmission method that may enhance a reception performance of a high power signal using a low power signal according to embodiments of the present invention.

Referring to FIG. 4, the hierarchical transmission method may modulate main service data in operation 410. Here, a channel coding with respect to the main service data may be performed.

In operation 420, the hierarchical transmission method may generate supplementary information data based on the main service data. The supplementary information data may refer to data that may be associated with the main service data based on a predetermined standard to enhance a reception performance of the main service data. In operation 430, the hierarchical transmission method may modulate the generated supplementary information data. Here, a channel coding with respect to the supplementary information data may be performed.

A modulation scheme with respect to the main service data may have a higher bitrate than a modulation scheme with respect to the supplementary information data.

The main service data may be modulated as a high power signal, and the supplementary information data may be modulated as a low power signal.

In operation 440, the hierarchical transmission method may combine the modulated main service data and the modulated supplementary information data.

In operation 450, the hierarchical transmission method may transmit the combined data to a reception apparatus.

The above-described hierarchical modulation method may enhance a reception performance of a high power signal using a low power signal. The above-described embodiments with reference to FIGS. 1 through 3 may be applied to a method of enhancing a reception performance of a high power signal using a low power signal and thus, further descriptions will be omitted herein.

The methods according to the above-described embodiments may be recorded in non-transitory computer-readable media including program instructions to implement various operations embodied by a computer. The media may also include, alone or in combination with the program instructions, data files, data structures, and the like. Examples of non-transitory computer-readable media include magnetic media such as hard disks, floppy disks, and magnetic tape; optical media such as CD ROM disks and DVDs; magneto-optical media such as optical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described embodiments, or vice versa.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A hierarchical transmission apparatus, comprising:
a main service modulator to modulate main service data;
a supplementary information generator to generate supplementary information data associated with the main service data based on the main service data;
a supplementary information modulator to modulate the supplementary information data;
a signal combiner to combine an output of the main service modulator and an output of the supplementary information modulator; and
a signal transmitter to transmit a signal generated by combining the output of the main service modulator and the output of the supplementary information modulator.

2. The hierarchical transmission apparatus of claim 1, wherein the supplementary information generator generates the supplementary information data associated with the main service data based on a predetermined standard to enhance a reception performance of the main service data.

3. The hierarchical transmission apparatus of claim 1, wherein the main service modulator modulates the main service data using a modulation scheme having a same bitrate as a bitrate of a modulation scheme of the supplementary information modulator, or having a higher bitrate than the bitrate of the modulation scheme of the supplementary information modulator.

4. The hierarchical transmission apparatus of claim 1, wherein each of the main service modulator and the supplementary information modulator respectively modulates each of the main service data and the supplementary information data, each using a different modulation scheme.

5. The hierarchical transmission apparatus of claim 1, wherein the main service modulator comprises a main service channel encoder to perform a channel coding with respect to the main service data.

6. The hierarchical transmission apparatus of claim 1, wherein the supplementary information modulator comprises a supplementary information channel encoder to perform a channel coding with respect to the supplementary information data.

7. The hierarchical transmission apparatus of claim 1, wherein the signal combiner combines an output of the main service modulator and an output of the supplementary information modulator using a superposition coding scheme.

8. A hierarchical transmission method, comprising:
modulating main service data;
generating supplementary information data associated with the main service data based on the main service data;
modulating the supplementary information data;
combining the modulated main service data and the modulated supplementary information data; and
transmitting the combined data.

9. The hierarchical transmission method of claim 8, wherein the generating of the supplementary information data comprises generating the supplementary information data associated with the main service data based on a predetermined standard to enhance a reception performance of the main service data.

10. The hierarchical transmission method of claim 8, wherein the modulating of the main service data comprises modulating the main service data using a modulation scheme having a same bitrate as a bitrate of a modulation scheme of the modulating of the supplementary information data, or having a higher bitrate than the bitrate of the modulation scheme of the modulating of the supplementary information data.

11. The hierarchical transmission method of claim 8, wherein each of the modulating of the main service data and the modulating of the supplementary information data respectively comprises modulating each of the main service data and the supplementary information data, each using a different modulation scheme.

12. The hierarchical transmission method of claim 8, wherein the modulating of the main service data comprises performing a channel coding with respect to the main service data.

13. The hierarchical transmission method of claim 8, wherein the modulating of the supplementary information data comprises performing a channel coding with respect to the supplementary information data.

14. The hierarchical transmission method of claim 8, wherein the combining of the modulated main service data and the modulated supplementary information data comprises combining the modulated main service data and the modulated supplementary information data using a superposition coding scheme.

15. A reception apparatus of a hierarchical transmission signal, the reception apparatus comprising:
an antenna to receive a signal from a transmission apparatus; and
a demodulator to demodulate the received signal,
wherein the signal is generated by combining modulated main service data and modulated supplementary information data.

16. The reception apparatus of claim 15, wherein the supplementary information data is associated with the main service data, and is generated based on a predetermined standard to enhance a reception performance of the main service data.

17. The reception apparatus of claim 15, wherein a bitrate of the modulated main service data is same as a bitrate of the modulated supplementary information data or a higher bitrate of the modulated supplementary information data.
